(19) United States
(12) Patent Application Publication
(10) Pub. No.: US 2013/0043417 A1
(43) Pub. Date: Feb. 21, 2013

(54) Solenoid Valve and Method for the Production Thereof

(71) Applicant: Harald Guggenmos, Immenstadt/Seifen (DE)

(72) Inventor: Harald Guggenmos, Immenstadt/Seifen (DE)

(73) Assignee: Robert Bosch GmbH, Stuttgart (DE)

(21) Appl. No.: 13/519,891

(22) PCT Filed: Nov. 4, 2010
(86) PCT No.: PCT/EP2010/066783

§ 371 Date: Oct. 22, 2012

(30) Foreign Application Priority Data
Dec. 29, 2009 (DE) 10 2009 055 380.0

(51) Int. Cl. F16K 31/02; H05K 13/00

(52) U.S. Cl. 251/129.15; 29/592.1

(57) ABSTRACT

A solenoid valve includes a housing, a pole core and a displaceably mounted armature which is at least partially accommodated in the housing. The housing is embodied as a single-part housing pot-shaped element having a cover wall and a base wall. The pole core is compressed axially in the housing pot-shaped element until it is in a desired axial position, and a first front side of the pole core is opposite the base wall and a second front side of the pole core, opposite the first front side, is opposite the armature. A method for producing said type of solenoid valve is also disclosed.

The invention relates to a solenoid valve comprising a housing, a pole core and a displaceably mounted armature which is received, at least in part, in the housing. The invention also relates to a method for producing such a solenoid valve.

### PRIOR ART

Solenoid valves of the generic type are known. For example, they are used as control and regulating valves for various media, in particular as hydraulic valves for brake circuits of motor vehicles. In the prior art, embodiments are known which are closed currentlessly, for example in the form of “exhaust valves”, which have a pole core inserted over portions into an open-ended sleeve and welded to said open-ended sleeve in the end region thereof.

A solenoid coil, which allows operation of the solenoid valve by an electromagnetic field to be directed by means of the pole core, is placed over the pole core, said electromagnetic field acting on a displaceably mounted armature which is received, at least in part, in the housing for actuation of said armature in the axial direction. At the housing end opposite the pole core, the housing has a housing termination which surrounds the armature and has a through-opening for the medium, in particular in the end face, said through-opening being closed in the currentless state for example by a sealing cone held on the end face of the armature; a helical compression spring is arranged between the armature and the pole core to ensure this seal and presses the armature in the currentless state away from the pole core and thus places the sealing cone onto the through-opening in a sealing manner. Between the pole core and the armature, a working space is formed as a working gap and, when the magnetic field acts against the effect of the helical compression spring, makes it possible to move the armature toward the pole core so that the sealing core releases the through-opening for the medium. The pole core is held at its end of the housing sleeve by means of the weld seam, which, for sealing reasons, runs through 360° in the peripheral direction, preferably more than 360°. The pole core is thus prevented from falling out of the housing sleeve and from being displaced therein. The welding process is costly, both in terms of the technical precision and process time required. In particular, the pole core has to be arranged in a precisely determined position within the housing sleeve and has to be held in place precisely enough during the welding process to produce the desired, defined valve opening. Inaccuracies in the adjustment of the position of the pole core within the housing sleeve lead to undesirable valve function.

### DISCLOSURE OF THE INVENTION

The aforementioned disadvantages are advantageously avoided by the proposed solenoid valve, which comprises a housing, a pole core and a displaceably mounted armature which is received, at least in part, in the housing. The housing is formed as a one-part housing pot with an outer wall and a base wall, wherein, in the housing pot, the pole core is impressed axially into a desired axial position, and wherein a first end face of the pole core opposes the base wall and a second end face of the pole core, opposite the first end face, opposes the armature. The housing consequently is not formed as a housing sleeve which is open on both sides, but as a housing pot, to a certain extent in the form of a capsule, wherein the pole core is inserted from the opening and is impressed axially into the desired axial position necessary for normal valve function. By contrast to the prior art, the pole core is thus not inserted (in part) from the outside into the opening in a housing sleeve provided to accommodate said pole core and fixed in place without welding, but is introduced from the opposite side, which forms or receives the termination of the housing on the side of the valve seal. The pole core is inserted into the housing pot until it has reached its desired axial position. It is held in this position by the housing pot.

The outer wall is preferably smaller in diameter compared to a peripheral wall of the pole core. When considering the respective diameters of the housing in the region of its outer wall and of the pole core in the region of its peripheral wall, the diameter of the outer wall (inner face), that is to say facing the peripheral wall of the pole core, is smaller to a certain extent. The pole core is thus inserted into the housing pot under bias and, as a result of the smaller diameter of the outer wall and the bias thus created, is held reliably in the desired axial position. Additional welding or compression is not necessary.

In a further preferred embodiment, the pole core has at least one pressure compensation duct which runs from the first end face to the second end face. The pressure compensation duct, which runs from the first end face of the pole core to the second end face thereof, for example in the form of a bore through the pole core, allows the medium to be controlled or switched to flow through the pole core from either side, the pole core therefore not being pressurized by the medium on one side only. In hydraulic valves of brake systems of motor vehicles, for example in ABS or ESP systems, very high pressures sometimes occur in the medium and, if such a pressure compensation duct were not provided, could lead to an undesired axial displacement of the pole core toward the base wall of the housing pot over long operating periods, thus changing the working space between the pole core and the armature, which is undesirable, and possibly affecting the function of the valve, which is also undesirable. By contrast, the pressure compensation duct ensures that the same pressure conditions are provided at both end faces of the pole core so that the pole core is subjected to pressures of equal magnitude in the axial direction, said pressures acting on both end faces. An axial displacement of the pole core as a result of pressure load by the medium is thus avoided effectively.

The pressure compensation duct is preferably a groove in the peripheral wall or a deviation from the geometry of the peripheral wall, for example a flattening which leaves a specific amount of space between the outer wall of the housing and the region of the peripheral wall, the pressure compensation duct being formed in this space. Advantageously, a bore therefore does not have to be introduced into the pole core, thus saving a machining step.

A method is also proposed for producing a solenoid valve which has a housing, a pole core and a displaceably mounted armature which is received, at least in some regions, in the housing. The housing is formed as a one-part housing pot with an outer wall and a base wall, and the pole core is impressed axially into the housing pot until reaching a desired axial position, in such a way that a first end face of the pole core opposes the base wall and the armature is inserted into the housing such that it opposes a second end face of the pole core opposite the first end face. The first end face of the pole core consequently is inserted into the housing pot in such a way that it opposes the base wall and encloses a volume between itself and the base wall; the second end face opposite said first end face opposes the armature.

The pole core is preferably impressed axially into the housing with the armature. Both the pole core and the armature therefore can be introduced into the housing by means of an economical process, wherein only one operational procedure is necessary.

The pole core is particularly preferably impressed into the housing by means of the armature until a valve element located on a side of the armature facing away from the pole core adopts a selectable axial opening position. The valve element is arranged on an end face of the armature facing away from the pole core, for example in the form of a sealing cone. This valve element opens or closes an opening located in a housing closure element so as to allow the medium to flow through. The function of the valve is primarily determined by the fact that this opening is opened to a desired extent, that is to say a specific volume flow rate per unit of time can pass through. This is determined by the opening stroke of the armature, which in turn is determined by the position of the pole core inside the housing; more specifically, a working space is provided between the pole core and the armature and is used when the valve is opened by the armature in the direction of the pole core. With the proposed impression of the pole core by means of the armature, the desired axial opening position can be adjusted very easily by impressing the pole core into the housing by means of the armature precisely as far as the point required for the desired axial opening position, and by terminating the impression precisely at this moment. The desired valve function is thus ensured without further adjustment and reworking.

Furthermore, the pole core and the armature are introduced into the housing in the same direction of insertion.

Further advantageous embodiments will become clear from the dependent claims and from combinations thereof.

The invention will be described in greater detail hereinafter on the basis of an exemplary embodiment, but is not limited thereto.

### IN THE DRAWINGS

FIG. 1 shows a solenoid valve according to the invention with a housing pot, and

FIG. 2 shows the impression of the pole core into the housing pot by means of the armature until the desired axial position is reached.

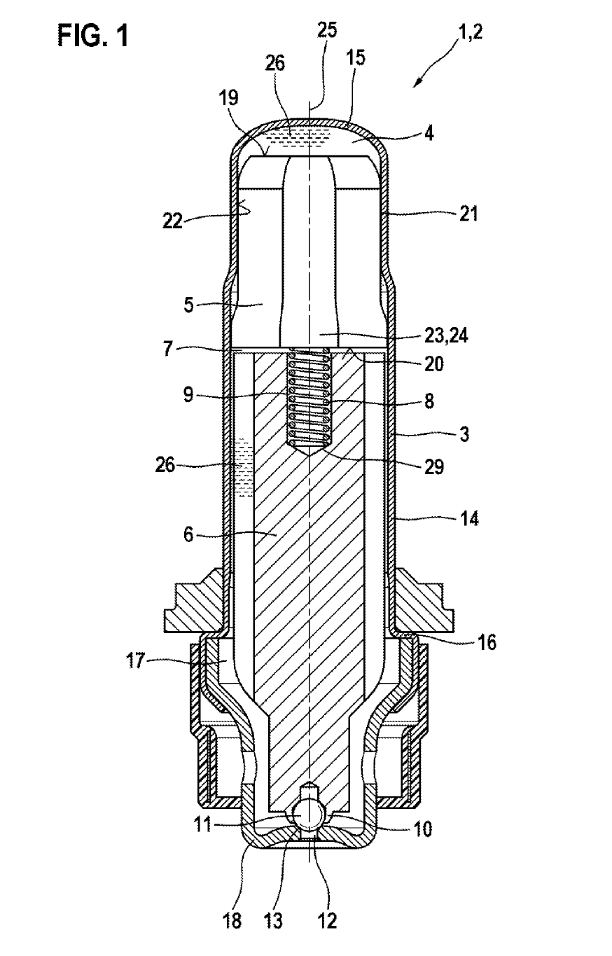

FIG. 1 shows a solenoid valve 1, namely an exhaust valve 2 closed currentlessly. The solenoid valve 1 has a housing 3, which surrounds a pole core 5 arranged in the longitudinal extension of the housing 3 in the region of a first end 4 and also an armature 6 adjoining said pole core in the axial direction, wherein, in the currentless state and for axial movement of the armature 6, said armature 6 is held by an approximately gap-width working space 7 from the pole core 5 under the effect of a helical compression spring 8 which is supported on the pole core 5 and on a base 29 of an elongate bore 9 formed in the armature 6. At the end 10 opposite the elongate bore 9 for receiving the helical compression spring 8, the armature 6 has a sealing cone 11 which seals a valve opening 12 formed in the housing 3 via the valve seat 13 surrounding said valve opening in the illustrated, currentless state of the solenoid valve 1. The housing 3 is formed of a one-part housing pot 14 which, at the first end 4 of the housing 3, is terminated by a base wall 15 and, at the second end 16 opposite the first end 4, has an expanded opening 17 which is sealed by means of a housing termination 18 once the pole core 5 and the armature 6 as well as other valve components have been introduced. The valve seat 13 is formed in the housing termination 18. Consequently, the armature 6 is only received in part in the housing 3, namely the housing pot 14, namely as far as the connection of the housing termination 18 to the housing pot 14; by contrast, the pole core 5 is encompassed completely by the housing pot 14. The pole core 5 has a first end face 19, which opposes the base wall 15 of the housing pot, and a second end face 20, which is opposite the first end face 19 and which opposes the armature 6. The pole core 5 has a substantially circle-like, preferably circular, cross-section, which is defined by a peripheral wall 21 of the pole core 5. The peripheral wall 21 of the pole core 5 abuts an outer wall 22 of the housing pot 14. The outer wall 22 is smaller in diameter compared to the pole core 5, in particular the peripheral wall 21 of the pole core 5, and therefore the pole core 5 is held under bias in the region of the outer wall 22, as illustrated. The pole core 5 further has a pressure compensation duct 23 extended in the axial direction and formed in this case as a groove 24 in the peripheral wall 21 in the axial direction. Any other shape deviating, that is to say regressing, from the geometry of the peripheral wall 21 toward the center (longitudinal axis 25 of the solenoid valve 1) and running in the axial direction of the pole core 5 from the first end face 19 to the second end face 20 can also be used instead of the groove 24; bores (not illustrated) which run from the first end face 19 to the second end face 20 may also be considered. The pressure compensation duct 23 is used to allow the medium 26, which flows around the armature 6 and to which the pole core 5 is exposed in the region of the second end face 20 thereof and which is connected by the solenoid valve 1, to flow into the region between the first end face 19 of the pole core 5 and the base wall 15 of the housing 3 so that the medium 26 flows over the pole core 5 on either side, namely from the first end face 19 and from the second end face 20, and therefore both end faces 19, 20 are subjected to equal pressure; an undesired axial displacement of the pole core 5 held in position between the peripheral wall 21 and the outer wall 22 of the housing 3 by the above-described bias is thus very advantageously avoided, said displacement being caused by pressurization on only one side by the medium 26, namely in the region of the second end face 20. There is no need to weld the pole core 5 to the housing 3, just as there is no need for additional compression of these parts.

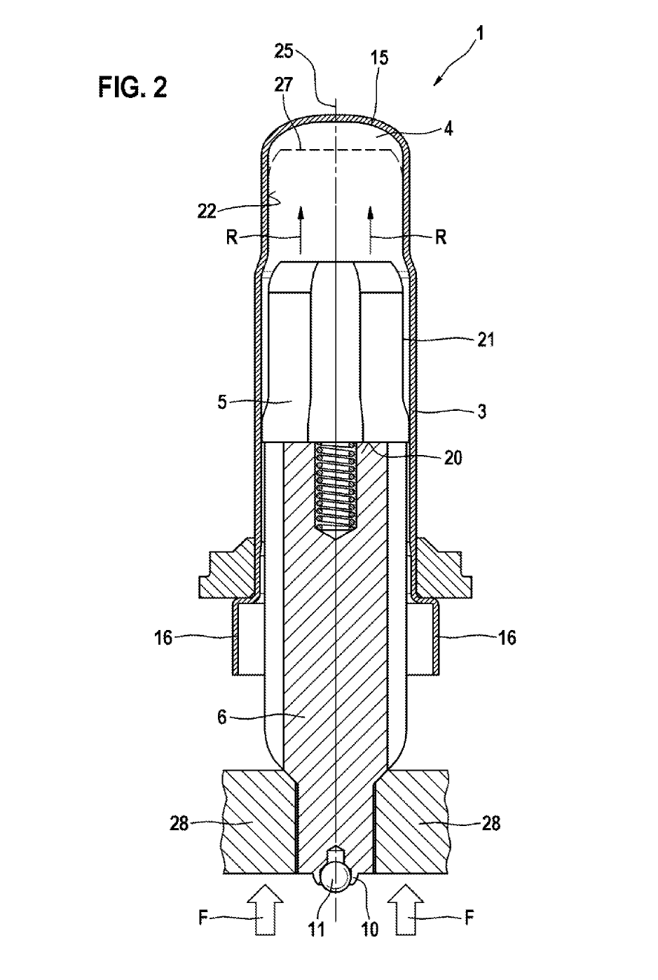

FIG. 2 shows the assembly of the solenoid valve 1, namely the introduction of the pole core 5 into the housing 3. To this end, the pole core 5 is introduced in the axial direction at the second end 16 of the housing 3, namely of the housing pot 14, and is moved into the housing 3 by the armature 6 in the direction of insertion R, namely axially toward the base wall 15. The housing 3 has a slightly wider diameter in the region of the second end 16 compared to in the region of its first end 4 so that the pole core 5 can be easily introduced over the armature 6 by the application of force. The pole core 5 has an expansion of diameter on the side facing the armature 6, that is to say basically in the region of the second end face 20, corresponding to a reduction in diameter close to its upper end, axially below the first end 4 of the housing 3. A maximum penetration depth of the pole core 5 is thus determined by way of design. The pole core 5 has such a diameter in the region of its upper end 27, said diameter being slightly greater than the inner diameter of the outer wall 22 of the housing 3; as a result of this smaller diameter of the outer wall 22 compared to the peripheral wall 21 of the pole core 5, a bias is produced, against which the pole core is pushed in the axial direction into its desired end position and final installed position 27; as a result of this bias, the pole core is automatically held in position as soon as the advancement in the direction of insertion R stops. The advancement in the direction of insertion R is caused by an application of force of the armature in the region of the end 10 thereof by a suitable advancing tool 28, wherein the advancing tool 28 preferably surrounds the region of the end 10 of the armature 6 in an annular manner and propels the pole core 5 and the armature 6 forward, precisely aligned with the longitudinal axis 25 of the housing 3. The force F acting on the armature 6 and on the pole core 5 is so great that it overcomes the bias produced by the smaller diameter of the outer wall 22 compared to the peripheral wall 21. The advancement by the advancing tool 28 is continued until the armature 6 has been received so far in the housing 3 that the sealing cone 11 is arranged in such an axial position relative to the housing 3 that, once the housing 3 has been sealed by the housing termination 18, the valve seat 13 shown in FIG. 1 is kept open and the medium 26 shown in FIG. 1 can flow through. The axial position of the pole core 5 thus can be adjusted directly very easily by the axial position, necessary for valve opening, of the sealing cone 11 connected to the armature 6, without the need for further adjustment or modification. The propulsion by the advancing tool 28 on the armature 6 by means of the force F ends simply at the moment at which the sealing cone 11 has reached the desired and necessary position in the axial direction. As a result of the bias, the pole core 5 is held in its final installed position 27 thus reached, and the opened working position of the solenoid valve 1 is provided upon contact between the armature 6 and the pole core 5. All in all, assembly occurs in the direction of insertion R. Once the pole core 5 and armature 6 have been introduced in the described manner, the housing termination 18 illustrated in FIG. 1 is applied, thus completing the solenoid valve 1.

1. A solenoid valve, comprising:
a housing,
a pole core, and
a displaceably mounted armature which is received, at least in part, in the housing,
wherein the housing is formed as a one-part housing pot with an outer wall and a base wall,
wherein the pole core is impressed axially into a desired axial position in the housing pot, and
wherein the pole core has (i) a first end face that opposes the base wall and, (ii) a second end face, opposite the first end face, that opposes the armature.

2. The solenoid valve as claimed in claim 1, wherein the outer wall is smaller in diameter compared to a peripheral wall of the pole core.

3. The solenoid valve as claimed in claim 1, wherein the pole core has at least one pressure compensation duct, which runs from the first end face to the second end face.

4. The solenoid valve as claimed in claim 3, wherein the at least one pressure compensation duct is configured as a groove in the peripheral wall.

5. A method for producing a solenoid valve which has a housing, a pole core and a displaceably mounted armature which is received, at least in some regions, in the housing, comprising:
forming the housing as a one-part housing pot with an outer wall and a base wall,
axially impressing the pole core into the housing pot until reaching a desired axial position, so that a first end face of the pole core opposes the base wall, and
inserting the armature into the housing such that the armature opposes a second end face of the pole core, opposite the first end face.

6. The method as claimed in claim 5, wherein the axially impressing step includes axially impressing the pole core into the housing with the armature.

7. The method as claimed in claim 5, wherein the axially impressing step includes axially impressing the pole core into the housing with the armature until a valve element located on a side of the armature facing away from the pole core adopts a selectable axial opening position.

8. The method as claimed in claim 5, wherein the pole core and the armature are introduced into the housing in the same direction of insertion.
